(19) United States
(12) Patent Application Publication
(10) Pub. No.: US 2019/0148132 A1
(43) Pub. Date: May 16, 2019

(54) METHOD OF MANUFACTURING SMALL-DIAMETER WAFER

(71) Applicant: DISCO CORPORATION, Tokyo (JP)

(72) Inventors: Hideji HORITA, Tokyo (JP); Sakae MATSUZAKI, Tokyo (JP); Noriko ITO, Tokyo (JP); Norihisa ARIFUKU, Tokyo (JP); Setsusei REI, Tokyo (JP); Akihito KAWAI, Tokyo (JP); Mai OGASAWARA, Tokyo (JP)

(21) Appl. No.: 16/184,022

(22) Filed: Nov. 8, 2018

(30) Foreign Application Priority Data
Nov. 14, 2017 (JP) 2017-218842

(51) Int. Cl. H01L 21/02; H01L 23/544

(52) U.S. Cl. CPC H01L 21/02035; H01L 21/02021; H01L 2223/54493; H01L 21/02013; H01L 23/544; H01L 21/02019

(57) ABSTRACT

A method of manufacturing a small-diameter wafer from a wafer having one face and the other face, the one face being mirror-polished, is provided. The method includes a protective member covering step of covering the one face of the wafer with a first protective member and the other face of the wafer with a second protective member, a cut-out step of cutting out a plurality of small-diameter wafers from the wafer covered with the first protective member and the second protective member, a chamfering step of chamfering an outer periphery portion of each of the plurality of small-diameter wafers, and a protective member removing step of removing the first protective member and the second protective member from each of the plurality of small-diameter wafers.

### BACKGROUND OF THE INVENTION

### Field of the Invention

The present invention relates to a method of manufacturing a small-diameter wafer to obtain a plurality of small-diameter wafers each having a small diameter from a single wafer.

### Description of the Related Art

Electrical equipment, typically a mobile phone or a personal computer, incorporates a device chip including a device such as an integrated circuit as an essential component thereof. For example, a device chip is obtained by demarcating a front surface side of a wafer formed of a semiconductor material such as silicon along a plurality of crossing division lines (streets) to thereby form a plurality of regions where a plurality of devices are formed individually and then, dividing the wafer into the device chips along the division lines.

In recent years, in order to enhance productivity of the device chip, use of wafer having a diameter of 12 in. (approximately 300 mm) or more (hereinafter, referred to as a large-diameter wafer) has become mainstream in producing a plurality of device chips. Meanwhile, when a large-diameter wafer is processed to produce a plurality of device chips, a large-sized apparatus corresponding to a diameter of the large-diameter wafer to be processed is required. Accordingly, for example, the large-diameter wafer is used to produce a small amount of device chips, resulting in pricing the device chip too high, in some cases.

To address this problem, a new production system has been considered in which a wafer having a small diameter, e.g. a diameter of substantially 3 in. (approximately 75 mm) (hereinafter, referred to as a small-diameter wafer) is used to produce a small amount of device chips. In this production system, various kinds of apparatuses are also miniaturized according to a size of the small-diameter wafer, so that the production system can achieve low costs and save space. Note that the small-diameter wafer used in this production system is, for example, manufactured by a method of cutting out from the large-diameter wafer mentioned above (see, for example, Japanese Patent Laid-Open No. 2014-110411).

A specific process of manufacturing a small-diameter wafer is, for example, as follows. First, a back surface of a large-diameter wafer is ground to be thinned to a desired thickness. Next, the thinned large-diameter wafer is processed by being irradiated with a laser beam, and a plurality of small-diameter wafers are cut out from the large-diameter wafer. Then, an outer periphery portion of each of the plurality of small-diameter wafer thus cut out is chamfered. Moreover, a front surface of the small-diameter wafer with the outer periphery portion chamfered is subjected to etching and polishing to obtain a mirror surface. Thereafter, this small-diameter wafer is cleaned.

### SUMMARY OF THE INVENTION

In the method of manufacturing the small-diameter wafer mentioned above, however, it is required to mirror-polish a front surface of each of the plurality of small-diameter wafers obtained by being cut out from the large-diameter wafer, one by one. Consequently, productivity cannot be enhanced sufficiently. In addition, in processing the small-diameter wafer, the small-diameter wafer may have flaws or foreign matters on its front surface, causing degradation in quality of the small-diameter wafer.

It is therefore an object of the present invention to newly provide a method of manufacturing a small-diameter wafer which prevents degradation in quality of the small-diameter wafer while enhancing productivity thereof.

In accordance with an aspect of the present invention, there is provided a method of manufacturing a small-diameter wafer from a wafer having one face and the other face, the one face being mirror-polished, the method including a protective member covering step of covering the one face of the wafer with a first protective member and the other face of the wafer with a second protective member, a cut-out step of cutting out a plurality of small-diameter wafers from the wafer covered with the first protective member and the second protective member, a chamfering step of chamfering an outer periphery portion of each of the plurality of small-diameter wafers, and a protective member removing step of removing the first protective member and the second protective member from each of the plurality of small-diameter wafers.

In the aspect of the present invention, in the cut-out step, a laser beam of a wavelength to be absorbed by the wafer may be applied to the wafer to cut out the plurality of small-diameter wafers.

Also, in the aspect of the present invention, in the cut-out step, a laser beam of a wavelength to transmit through the wafer may be applied to the wafer such that a focal point of the laser beam is positioned inside the wafer to form a modified layer inside the wafer, thereby cutting out the plurality of small-diameter wafers.

Also, in the aspect of the present invention, in the cut-out step, the wafer may be hollowed by a core drill to cut out the plurality of small-diameter wafers.

Also, in the aspect of the present invention, in the cut-out step, part of the first protective member or the second protective member corresponding to an outline of each of the plurality of small-diameter wafers may be removed, and plasma etching may be performed on the wafer with the first protective member or the second protective member serving as a mask to cut out the plurality of small-diameter wafers.

Also, in the aspect of the present invention, the method may further include a grinding step of grinding a side of the other face of the wafer to thin the wafer to a predetermined thickness, before covering the other face of the wafer with the second protective member.

Also, in the aspect of the present invention, the method may further include a mark forming step of forming a mark indicating a crystal orientation of the small-diameter wafer on the one face or the other face of the wafer, before the small-diameter wafer is cut out from the wafer.

Also, in the aspect of the present invention, the method may further include a pick-up step of picking up the small-diameter wafer, after the small-diameter wafer is cut out from the wafer.

Also, in the aspect of the present invention, the method may further include a cleaning step of cleaning the small-diameter wafer, after the first protective member and the second protective member are removed from the small-diameter wafer.

In the method of manufacturing a small-diameter wafer according to the aspect of the present invention, a plurality of small-diameter wafers are cut out from a wafer one face of which has been mirror-polished in advance, and accordingly, it is not necessary to mirror-polish the cut-out small-diameter wafer. In other words, since the plurality of small-diameter wafers having been cut out do not need to be mirror-polished individually, productivity of the small-diameter wafer is enhanced.

Also, in the method of manufacturing a small-diameter wafer according to the aspect of the present invention, the plurality of small-diameter wafers are cut out from the wafer in a state in which the one face of the wafer is covered with the first protective member and the other face of the wafer is covered with the second protective member, and therefore, a risk of having flaws or foreign matters on a surface of the small-diameter wafer is kept low in cutting out. Accordingly, degradation in quality of the small-diameter wafer can be prevented.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a configuration example of a wafer;

FIG. 2A is a perspective view schematically illustrating a state in which a first face of the wafer is covered with a first protective member;

FIG. 2B is a perspective view schematically illustrating a state in which a second face of the wafer is covered with a second protective member;

FIG. 3 is a perspective view schematically illustrating a manner in which marks indicating the crystal orientation are formed in regions of the wafer to be small-diameter wafers;

FIG. 4 is a perspective view schematically illustrating a manner in which the small-diameter wafers are cut out from the wafer;

FIG. 5 is a perspective view schematically illustrating a manner in which the small-diameter wafer is picked up;

FIG. 6 is a perspective view schematically illustrating a manner in which an outer periphery portion of the small-diameter wafer is chamfered;

FIG. 7 is a perspective view schematically illustrating the small-diameter wafer after the first protective member and the second protective member are removed;

FIG. 8 is a perspective view schematically illustrating a manner in which the small-diameter wafers are cut out from the wafer in a cut-out step according to a first modification example;

FIG. 9 is a perspective view schematically illustrating a manner in which part of the second protective member is removed in a cut-out step according to a second modification example; and

FIG. 10 is a perspective view schematically illustrating a manner in which the small-diameter wafers are cut out from the wafer in the cut-out step according to the second modification example.

### DETAILED DESCRIPTION OF THE PREFERRED EMBODIMENT

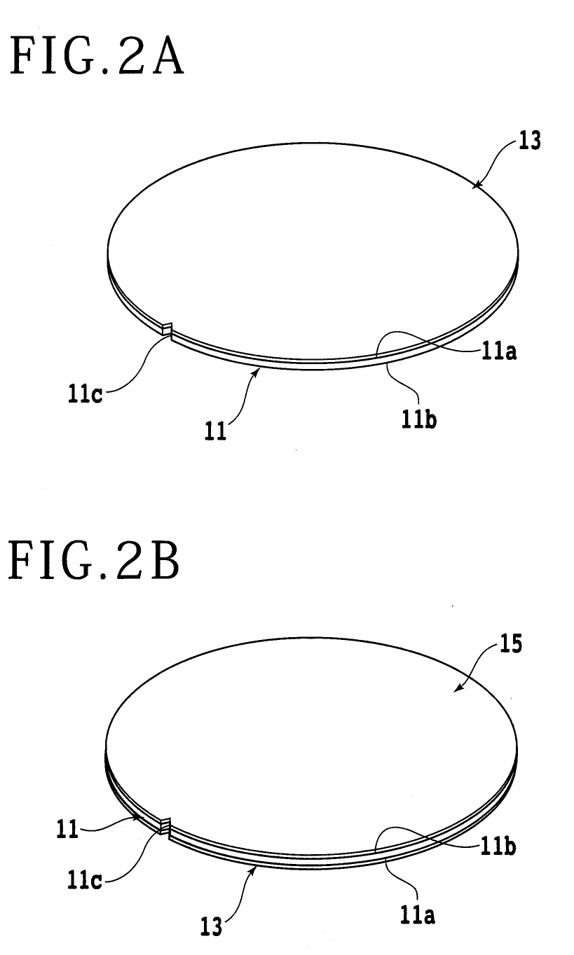

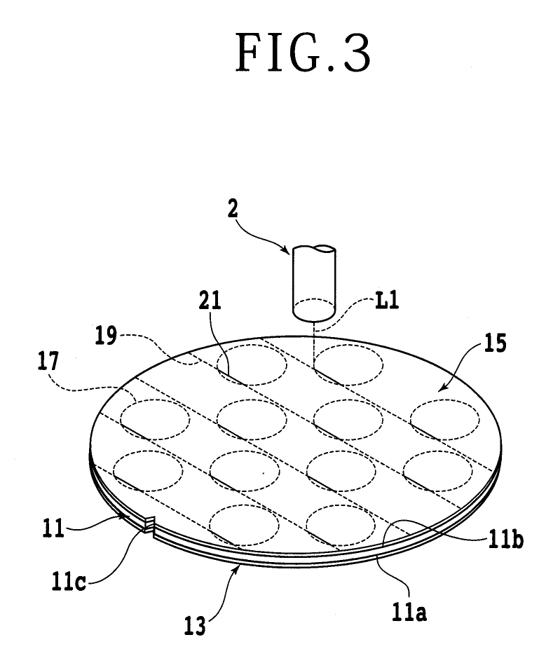

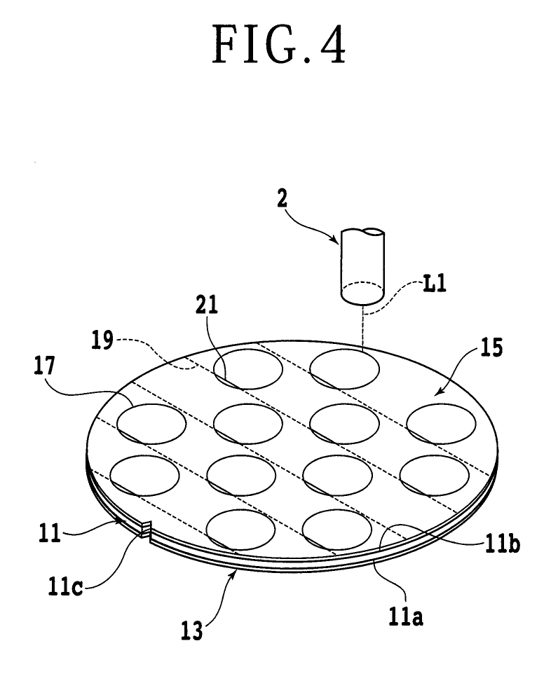

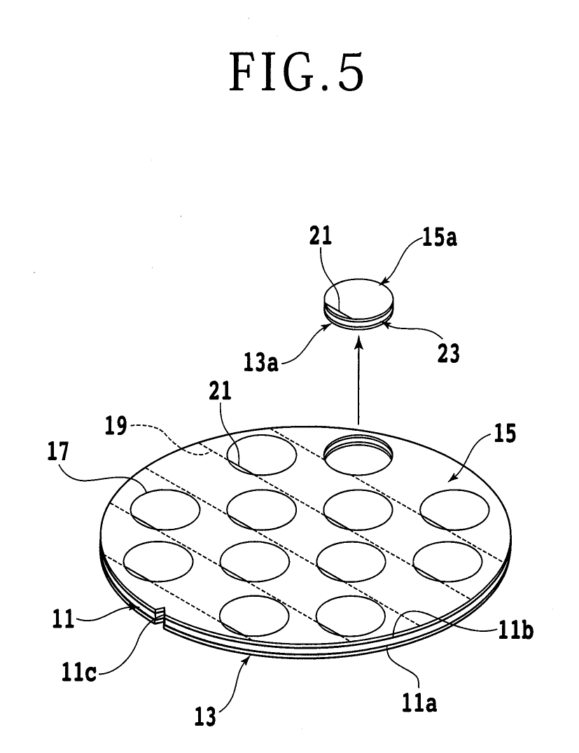

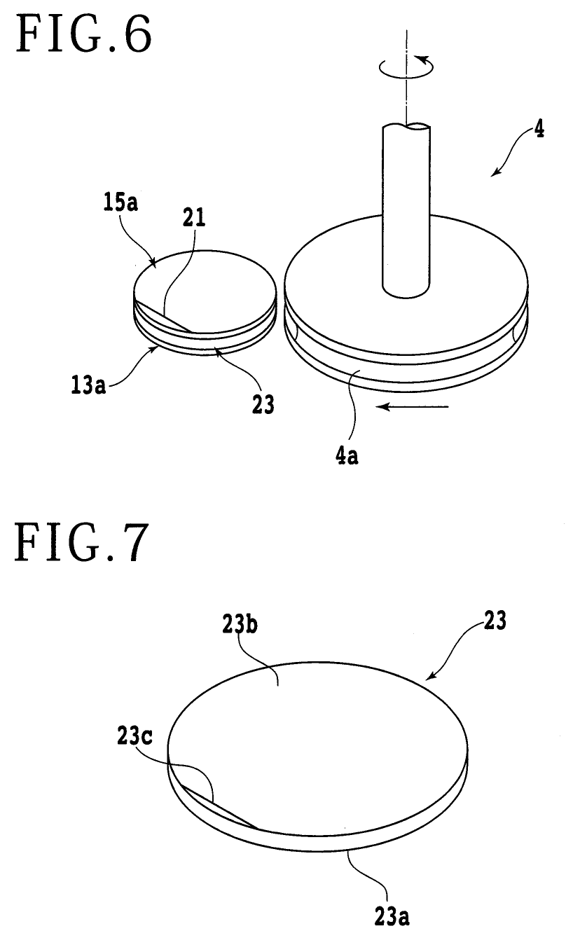

An embodiment according to an aspect of the present invention will be described with reference to the attached drawings. A method of manufacturing a small-diameter wafer according to the present embodiment includes a protective member covering step (see FIGS. 2A and 2B), a mark forming step (see FIG. 3), a cut-out step (see FIG. 4), a pick-up step (see FIG. 5), a chamfering step (see FIG. 6), a protective member removing step (see FIG. 7), and a cleaning step.

In the protective member covering step, a first face (one face) of a wafer which is mirror-polished is covered with a first protective member, and a second face (the other face) opposite to the first face is covered with a second protective member. In the mark forming step, a mark indicating the crystal orientation is formed in a region to be a small-diameter wafer on the second face side of the wafer. In the cut-out step, a plurality of small-diameter wafers are cut out from the wafer covered with the first protective member and the second protective member.

In the pick-up step, the plurality of small-diameter wafers having been cut out from the wafer are picked up. In the chamfering step, an outer periphery portion of each of the small-diameter wafers is chamfered. In the protective member removing step, the first protective member and the second protective member are removed from the small-diameter wafer. In the cleaning step, each of the small-diameter wafers is cleaned. Hereinafter, the method of manufacturing a small-diameter wafer according to the present embodiment will be described in detail.

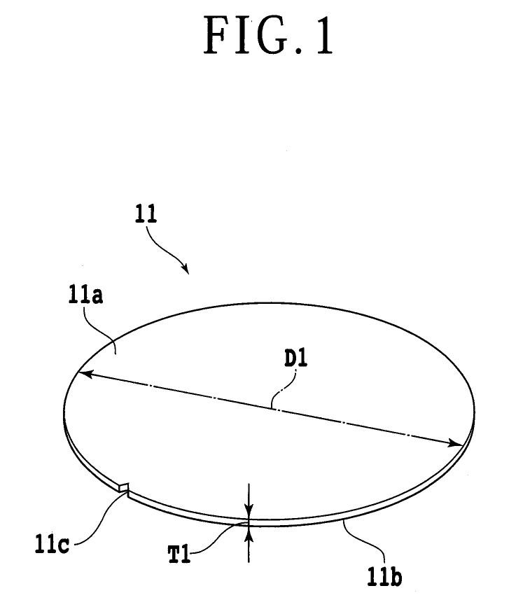

FIG. 1 is a perspective view schematically illustrating a configuration example of a wafer 11 to be used in the method of manufacturing a small-diameter wafer according to the present embodiment. The wafer 11 to be used in the present embodiment is, for example, formed in a disc shape using a crystalline silicon (Si), and the wafer 11 has a first face (one face) 11a which is mirror-polished and substantially flat, and a second face (the other face) 11b which is opposite to the first face 11a. Note that the second face 11b is substantially parallel to the first face 11a.

An outer peripheral edge of the wafer 11 is provided with a notch 11c indicating the crystal orientation. However, in place of the notch 11c, an orientation flat or the like may be provided. A diameter (D1) of the wafer 11 is larger than a diameter of a small-sized wafer manufactured in the present embodiment. Also, a thickness (T1) of the wafer 11 is equal to or greater than a thickness of the small-sized wafer manufactured in the present embodiment.

Note that, although the disc-shaped wafer 11 formed of crystalline silicon is used in the present embodiment, a material, a shape, a structure, a size, and the like of the wafer 11 are not limited. For example, a substrate including a material such as other semiconductor, ceramic, resin, or metal may be used for the wafer 11. Also, although the wafer 11 having the mirror-polished first face 11a is used in the present embodiment, the wafer 11 with the first face 11a and the second face 11b both mirror-polished may be used.

In the method of manufacturing a small-diameter wafer in the present embodiment, first, the protective member covering step is performed in which the first face 11a of the above-mentioned wafer 11 is covered with the first protective member and the second face 11b is covered with the second protective member. FIG. 2A is a perspective view schematically illustrating a state in which the first face 11a of the wafer 11 is covered with the first protective member 13, and FIG. 2B is a perspective view schematically illustrating a state in which the second face 11b of the wafer 11 is covered with the second protective member 15.

As illustrated in FIG. 2A, in the protective member covering step according to the present embodiment, first, the first face 11a of the wafer 11 is covered with the first protective member 13. Although a manufacturing process, a material, a thickness, and the like of the first protective member 13 are not particularly limited, a method in which a negative resist material such as cyclized rubber is applied to the first face 11a of the wafer 11 for exposure is used in the present embodiment, whereby the first protective member 13 having a thickness of substantially 10 μm is formed.

After the first face 11a of the wafer 11 is covered with the first protective member 13, as illustrated in FIG. 2B, the second face 11b of the wafer 11 is covered with the second protective member 15. Although a manufacturing process, a material, a thickness, and the like of the second protective member 15 are also not particularly limited, the second protective member 15 is formed with the same material as the first protective member 13 to have a thickness equivalent to that of the first protective member 13 in the same manufacturing process as that of the first protective member 13, in the present embodiment.

Note that application of the negative resist material can be performed by spin coating, spray coating, dipping, screen printing, or other methods, for example. Also, in the present embodiment, the first face 11a is covered with the first protective member 13 before the second face 11b is covered with the second protective member 15. Alternatively, the second face 11b is covered with the second protective member 15, and then, the first face 11a may be covered with the first protective member 13. By use of a water-soluble resin, a protective tape, or the like, in addition to the negative resist material, the first protective member 13 and the second protective member 15 can be also formed.

After the protective member covering step is performed, a mark forming step is performed in which a mark indicating the crystal orientation is formed in a region to be a small-diameter wafer on the second face 11b side of the wafer. FIG. 3 is a perspective view schematically illustrating a manner in which marks indicating the crystal orientation are formed in regions of the wafer 11 to be small-diameter wafers. This mark is formed, for example, using by a method of applying a laser beam L1 of such a wavelength as to be absorbed by the wafer 11 (wavelength having absorptivity) to the second face 11b of the wafer 11.

More specifically, first, as illustrated in FIG. 3, in such a manner as to overlap with a cut-out line 17 which is a reference used in cutting out a small-diameter wafer, a moving line 19 which is a reference of movement of a laser beam applying unit 2 is set on a front surface of the second protective member 15. Next, the laser beam applying unit 2 is placed on a side of the front surface (an opposite side of the front surface (first face 11a) of the wafer 11) of the second protective member 15, causing the laser beam applying unit 2 and the wafer 11 to move relatively in such a manner that the laser beam applying unit 2 moves along the moving line 19.

Then, at a timing at which the laser beam applying unit 2 moves in a range corresponding to a region surrounded by the cut-out line 17, the laser beam L1 is applied to the second face 11b of the wafer 11 from this laser beam applying unit 2. Note that an output and the like parameters of the laser beam L1 are adjusted in a range in which the second face 11b of the wafer 11 can be slightly processed through ablation with application of the laser beam L1.

Consequently, a mark 23c (see FIG. 7) indicating the crystal orientation can be formed in a region to be a small-diameter wafer on the second face 11b side of the wafer 11 by applying the laser beam L1 to a given mark forming line 21 partially overlapping with the moving line 19. This mark 23c is associated with the notch 11c of the wafer 11, so that the crystal orientation of the small-diameter wafer after being cut out from the wafer 11 can be checked according to the mark 23c. When the marks 23c are formed in all regions to be a small-diameter wafer, the mark forming step is finished.

Note that a shape, a direction, a size, and the like of the mark 23c which is formed in the mark forming step are not particularly limited. Also, in the present embodiment, although the mark 23c is formed by applying the laser beam L1 only to the region surrounded by the cut-out line 17, it is also possible to form the mark 23c by applying the laser beam L1 to the entire moving line 19.

Also, in the present embodiment, although the mark 23c is formed on the second face 11b of the wafer 11, it is also possible to form the mark 23c on the first face 11a of the wafer 11. Moreover, in the present embodiment, the mark 23c is formed through ablation processing by use of the laser beam L1; however, the mark 23c may be formed through cutting, drilling, etching, or the like processing.

After the mark forming step is performed, the cut-out step is performed in which a plurality of small-diameter wafers are cut out from the wafer 11 covered with the first protective member 13 and the second protective member 15. FIG. 4 is a perspective view schematically illustrating a manner in which the small-diameter wafers are cut out from the wafer 11. In the cut-out step, subsequent to the mark forming step, the laser beam applying unit 2 applying the laser beam L1 of such a wavelength as to be absorbed by the wafer 11 (wavelength having absorptivity) is used.

More specifically, as illustrated in FIG. 4, the laser beam applying unit 2 and the wafer 11 are moved relatively in such a manner that the laser beam applying unit 2 placed on the front surface side of the second protective member 15 moves along the cut-out line 17. At the same time, the laser beam applying unit 2 emits the laser beam L1 onto the second face 11b of the wafer 11. Note that the output of the laser beam L1, the number of applications of the laser beam L1, and the like are adjusted in a range in which the wafer 11 can be cut through ablation processing.

Accordingly, the laser beam L1 is applied along the cut-out line 17 to thereby cut out a small-diameter wafer 23 (see FIG. 5 etc.) from the wafer 11. Note that the small-diameter wafer 23 is cut out in a state in which a first face (one face) 23a thereof (see FIG. 7) is covered with a first protective member 13a (see FIG. 5 etc.) which is part of the first protective member 13 and a second face (the other face) 23b thereof (see FIG. 7) is covered with a second protective member 15a (see FIG. 5 etc.) which is part of the second protective member 15.

When all of the small-diameter wafers 23 are cut out from the wafer 11, the cut-out step is finished. Note that, in the present embodiment, the laser beam L1 is applied to the second face 11b of the wafer 11 to cut out the small-diameter wafer 23; however, it is also possible to cut out the small-diameter wafer 23 by applying the laser beam L1 to the first face 11a of the wafer 11.

After the cut-out step is performed, the pick-up step is performed in which the small-diameter wafer 23 having been cut out from the wafer 11 is picked up. FIG. 5 is a perspective view schematically illustrating a manner in which the small-diameter wafer 23 is picked up. The small-diameter wafer 23 is picked up, for example, by use of a pick-up tool (not illustrated) provided with a holding part which sucks the small-diameter wafer 23 to be held thereon.

More specifically, the holding part of the pick-up tool is brought into contact with the first protective member 13 or the second protective member 15 covering the small-diameter wafer 23, and the first protective member 13 or the second protective member 15 is sucked by the pick-up tool. Subsequently, the pick-up tool is moved in a direction away from the wafer 11, so that the small-diameter wafer 23 can be picked up.

After the pick-up step is performed, the chamfering step is performed in which the outer periphery portion of the small-diameter wafer 23 having been cut out from the wafer 11 is chamfered. FIG. 6 is a perspective view schematically illustrating a manner in which an outer periphery portion of the small-diameter wafer 23 is chamfered. In this method of chamfering the outer periphery portion of the small-diameter wafer 23, for example, a grinding stone 4 for chamfering which is formed in a cylindrical shape is rotated, and a side surface 4a of the grinding stone 4 is brought into contact with the outer periphery portion of the small-diameter wafer 23. Note that the side surface 4a of the grinding stone 4 is curved in a shape corresponding to the outer periphery portion of the small-diameter wafer 23 after being chamfered.

After the chamfering step is performed, the protective member removing step is performed in which the first protective member 13a and the second protective member 15a are removed from the small-diameter wafer 23. FIG. 7 is a perspective view schematically illustrating the small-diameter wafer 23 after the first protective member 13a and the second protective member 15a are removed. Since the negative resist material such as cyclized rubber is used for the first protective member 13a and the second protective member 15a in the present embodiment, the first protective member 13a and the second protective member 15a can be removed from the small-diameter wafer 23, for example, by use of a mixed solution of sulfuric acid and hydrogen peroxide solution.

Note that a specific process carried out in the protective member removing step is changed according to a material and the like of the first protective member 13a and the second protective member 15a. For example, in a case where the first protective member 13a and the second protective member 15a adopt a water-soluble resin, water and the like can be used to remove the first protective member 13a and the second protective member 15a from the small-diameter wafer 23. Alternatively, in a case where the first protective member 13a and the second protective member 15a adopt a protective tape or the like, the first protective member 13a and the second protective member 15a may be only peeled off from the small-diameter wafer 23 to be removed.

After the protective member removing step is performed, the cleaning step for cleaning the small-diameter wafer 23 is performed. In this cleaning step, a cleaning method referred to as RCA clean or the like is used. More specifically, for example, the small-diameter wafer 23 is first soaked into a mixed solution of an ammonium hydroxide solution and a hydrogen peroxide solution, then immersed in a solution of hydrofluoric acid, and after that, treated with a mixed solution of a solution of hydrochloric acid and hydrogen peroxide solution. Note that a specific type of cleaning carried out in the cleaning step is not particularly limited.

As described above, in the method of manufacturing a small-diameter wafer according to the present embodiment, the plurality of small-diameter wafers 23 are cut out from the wafer 11 with the first face (one face) 11a mirror-polished in advance, and accordingly, it is not necessary to mirror-polish the small-diameter wafer 23 having been cut out. Thus, the plurality of small-diameter wafers 23 having been cut out do not need to be mirror-polished individually, thereby enhancing productivity of the small-diameter wafers 23.

Also, in the method of manufacturing a small-diameter wafer according to the present embodiment, the plurality of small-diameter wafers 23 are cut out from the wafer 11 in a state in which the first face 11a of the wafer 11 is covered with the first protective member 13 and the second face (the other face) 11b is covered with the second protective member 15, whereby a risk of having flaws or foreign matters on its surface of the small-diameter wafer 23 is kept low in cutting out.

Similarly, the outer periphery portion of the small-diameter wafer 23 is chamfered in a state in which the first protective member 13a and the second protective member 15a cover the small-diameter wafer 23, whereby a risk of having flaws or foreign matters on its surface of the small-diameter wafer 23 is kept low in chamfering. Thus, degradation in quality of the small-diameter wafer 23 can be prevented.

Note that the present invention is not limited the foregoing embodiment and can be implemented by modifying in various ways. For example, although the plurality of small-diameter wafers 23 are cut out from the wafer 11 through ablation processing adopting the laser beam L1 of such a wavelength as to be absorbed by the wafer 11 (wavelength having absorptivity) in the foregoing embodiment, the plurality of small-diameter wafers 23 can be also cut out using a different method.

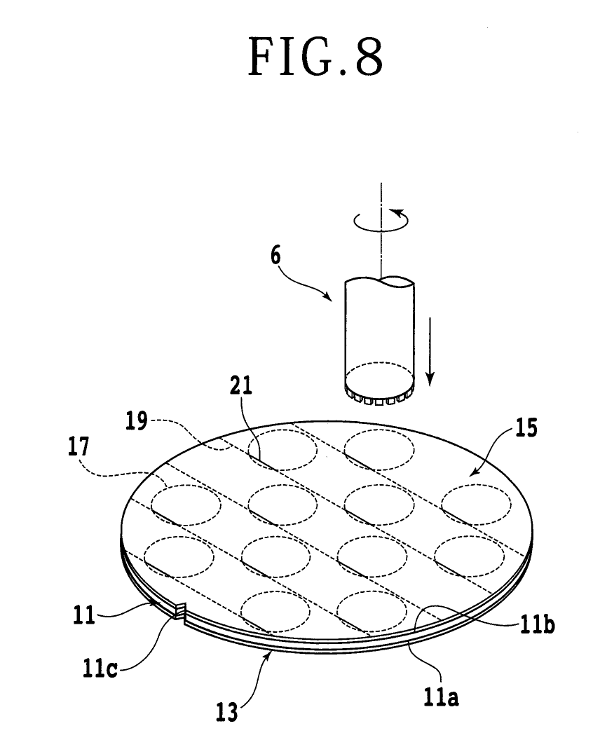

FIG. 8 is a perspective view schematically illustrating a manner in which the small-diameter wafer 23 are cut out from the wafer 11 in the cut-out step according to a first modification example. In the cut-out step according to the first modification example, a core drill 6 including a hollow body in a cylindrical shape and grinding blades (grinding stones) provided on a ring-shaped lower face of the hollow body is used.

More specifically, as illustrated in FIG. 8, the core drill 6 is rotated such that the cutting blades thereof are caused to cut into the wafer 11 along the cutting line 17. Accordingly, the core drill 6 hollows the wafer 11 along the cutting line 17, so that the small-diameter wafer 23 can be cut out from the wafer 11.

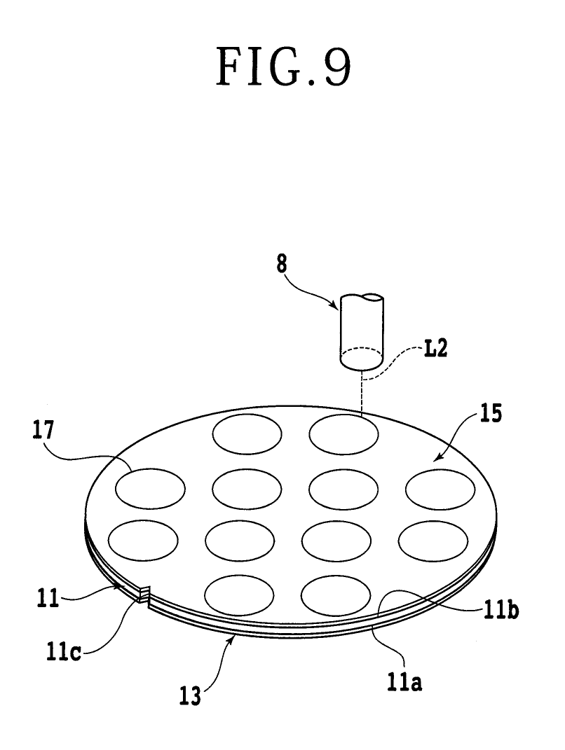

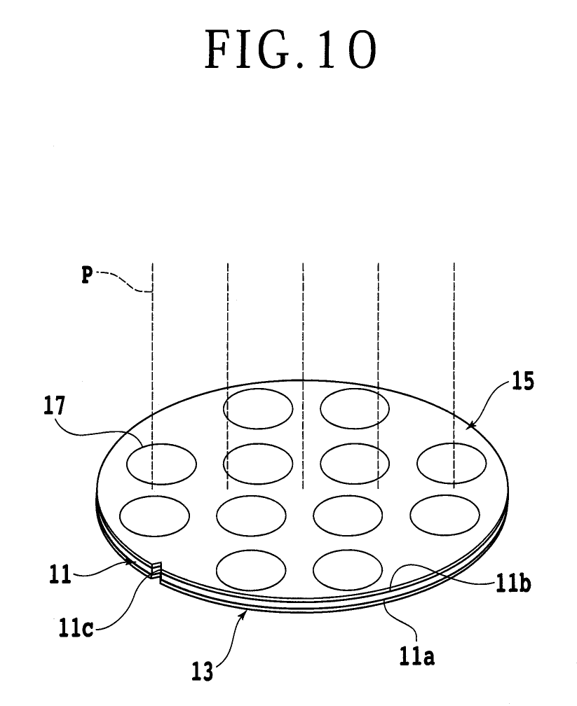

FIG. 9 is a perspective view schematically illustrating a manner in which part of the second protective member 15 is removed in the cut-out step according to a second modification example. FIG. 10 is a perspective view schematically illustrating a manner in which the small-diameter wafers 23 are cut out from the wafer 11 in the cut-out step according to the second modification example. In the cut-out step according to the second modification example, plasma etching is performed on the wafer 11 with the second protective member 15 as a mask to cut out the plurality of small-diameter wafers 23 from the wafer 11.

More specifically, first, as illustrated in FIG. 9, a laser beam applying unit 8 and the wafer 11 are moved relatively, and the laser beam applying unit 8 emits a laser beam L2 along a cut-out line 17 corresponding to an outline of the small-diameter wafer 23. Accordingly, part of the second protective member 15 corresponding to the outline of the small-diameter wafer 23 is removed. Note that, although the laser beam L2 having a wavelength in the infrared range or the ultraviolet range is used in the present embodiment, the wavelength of the laser beam L2 is not particularly limited.

After the part of the second protective member 15 corresponding to the outline of the small-diameter wafer 23 is removed along all of the cut-out lines 17, as illustrated in FIG. 10, the second face 11b of the wafer 11 is subjected to plasma etching with the second protective member 15 remaining on the second face 11b of the wafer 11 serving as a mask. Although a type of plasma P applied to the second face 11b of the wafer 11 is not particularly limited, plasma P generated from a reactive gas mixed with SF₆, O₂, and He is used in the present embodiment. Accordingly, the plurality of small-diameter wafers 23 can be cut out from the wafer 11 made of silicon at the same time.

Note that, although the part of the second protective member 15 is removed and plasma etching is performed on the second face 11b side of the wafer 11 in the second modification example described above, plasma etching may be also performed on the first face 11a side of the wafer 11 in the similar manner. In this case, the first protective member 13 may be used as a mask.

Also, as a third modification example, it is also possible to cut out the plurality of small-diameter wafers 23 using a method of applying a laser beam of such a wavelength as to transmit through the wafer 11 (wavelength having transmitting property). In this case, the laser beam is applied to the wafer 11 along each of the cut-out lines 17 such that a focal point of the laser beam is positioned inside the wafer 11.

Accordingly, a portion inside the wafer 11 can be modified to form a modified layer along each of the cut-out lines 17. Then, an external force is applied to each of the modified layers, so that the wafer 11 can be broken and divided along the modified layers. In other words, the small-diameter wafer 23 can be cut out from the wafer 11. Alternatively, an additional modified layer may be further formed in a region on an outer side of each of the cut-out lines 17 so as to easily cut out the small-diameter wafer 23 from the wafer 11.

As another alternative, before covering the second protective member 15 on the second face 11b of the wafer 11, a grinding step of grinding the second face 11b side of the wafer 11 may be performed to thin the wafer 11 to a predetermined thickness. Similarly, the wafer 11 may be also thinned by etching or the like method. Also, although the small-diameter wafer 23 having been cut out from the wafer 11 is picked up in the present embodiment, the remaining part of the wafer 11 from which the small-diameter wafers 23 have been cut out may be removed.

In addition, a structure, a method, or the like according to the foregoing embodiment and modification examples may be appropriately modified to be implemented within a range not deviating from an object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of manufacturing a small-diameter wafer from a wafer having one face and the other face, the one face being mirror-polished, the method comprising:
a protective member covering step of covering the one face of the wafer with a first protective member and the other face of the wafer with a second protective member;
a cut-out step of cutting out a plurality of small-diameter wafers from the wafer covered with the first protective member and the second protective member;
a chamfering step of chamfering an outer periphery portion of each of the plurality of small-diameter wafers; and
a protective member removing step of removing the first protective member and the second protective member from each of the plurality of small-diameter wafers.

2. The method of manufacturing a small-diameter wafer according to claim 1, wherein
in the cut-out step, a laser beam of a wavelength to be absorbed by the wafer is applied to the wafer to cut out the plurality of small-diameter wafers.

3. The method of manufacturing a small-diameter wafer according to claim 1, wherein
in the cut-out step, a laser beam of a wavelength to transmit through the wafer is applied to the wafer such that a focal point of the laser beam is positioned inside the wafer to form a modified layer inside the wafer, thereby cutting out the plurality of small-diameter wafers.

4. The method of manufacturing a small-diameter wafer according to claim 1, wherein
in the cut-out step, the wafer is hollowed by a core drill to cut out the plurality of small-diameter wafers.

5. The method of manufacturing a small-diameter wafer according to claim 1, wherein
in the cut-out step, part of the first protective member or the second protective member corresponding to an outline of each of the plurality of small-diameter wafers is removed, and plasma etching is performed on the wafer with the first protective member or the second protective member serving as a mask to cut out the plurality of small-diameter wafers.

6. The method of manufacturing a small-diameter wafer according to claim 1, the method further comprising:
a grinding step of grinding a side of the other face of the wafer to thin the wafer to a predetermined thickness, before covering the other face of the wafer with the second protective member.

7. The method of manufacturing a small-diameter wafer according to claim 1, the method further comprising:
a mark forming step of forming a mark indicating a crystal orientation of the small-diameter wafer on the one face or the other face of the wafer, before the small-diameter wafer is cut out from the wafer.

8. The method of manufacturing a small-diameter wafer according to claim 1, the method further comprising:
a pick-up step of picking up the small-diameter wafer, after the small-diameter wafer is cut out from the wafer.

9. The method of manufacturing a small-diameter wafer according to claim 1, the method further comprising:
a cleaning step of cleaning the small-diameter wafer, after the first protective member and the second protective member are removed from the small-diameter wafer.
